(19) United States
(12) Patent Application Publication
(10) Pub. No.: US 2026/0054660 A1
(43) Pub. Date: Feb. 26, 2026

(54) COOLING STRUCTURE FOR IN-VEHICLE ECU

(71) Applicant: TOYOTA JIDOSHA KABUSHIKI KAISHA, Toyota-shi (JP)

(72) Inventor: Koji SAEKI, Okazaki-shi (JP)

(73) Assignee: TOYOTA JIDOSHA KABUSHIKI KAISHA, Toyota-shi (JP)

(21) Appl. No.: 19/079,474

(22) Filed: Mar. 14, 2025

(30) Foreign Application Priority Data
Aug. 21, 2024 (JP) 2024-140094

(51) Int. Cl. B60R 13/08; B60R 16/023; B62D 25/02; B62D 25/16; B62D 29/00; H05K 7/20

(52) U.S. Cl. CPC B60R 13/0869; B60R 16/0239; B62D 25/02; B62D 25/16; B62D 29/008; H05K 7/20854; B60R 16/0231

(57) ABSTRACT

A cooling structure for an in-vehicle ECU includes: a body component that is part of a vehicle body; and an ECU attached to the body component. The body component includes a heatsink on the back side of a portion of the body component to which the ECU is attached. The body component is a single-piece aluminum diecast component including the heatsink.

### CROSS-REFERENCE TO RELATED APPLICATION

This application claims priority to Japanese Patent Application No. 2024-140094 filed on Aug. 21, 2024. The disclosure of the above-identified application, including the specification, drawings, and claims, is incorporated by reference herein in its entirety.

### BACKGROUND

### 1. Technical Field

The present specification discloses cooling structures for electronic control units (hereinafter referred to as “ECU”) mounted on vehicles.

### 2. Description of Related Art

An ECU is a device that controls driving of electronic components mounted on a vehicle. Such a ECU is disposed in an unused space in a vehicle. An ECU typically includes a signal circuit and a power supply circuit, and generates heat while being driven. An ECU degrades or malfunctions at excessively high temperatures. Therefore, it has been proposed to attach a heatsink to an ECU in order to efficiently cool the ECU.

Japanese Unexamined Patent Application Publication No. 2018-039497 (JP 2018-039497 A) discloses a heatsink that improves heat dissipation performance. The heatsink of JP 2018-039497 A includes a heat dissipation base and a plurality of heat dissipation fins standing from a surface of the heat dissipation base. The heat dissipation fins are formed by diecasting and are integral with the heat dissipation base. This heatsink improves heat transfer efficiency from the heat dissipation base to the heat dissipation fins and further improves the heat dissipation performance.

### SUMMARY

However, the heatsink of JP 2018-039497 A is a separate component independent of body components of a vehicle and an ECU. Therefore, a dedicated process is required to manufacture the heatsink, and a dedicated space for mounting the heatsink is also required. Moreover, in order to improve heat dissipation capability of a heatsink, it is necessary to increase the surface area of the heatsink. However, it is typically difficult to significantly increase the size of a heatsink, and it is therefore difficult to sufficiently increase the surface area of a heatsink.

In view of the above, the present disclosure discloses a cooling structure for an in-vehicle ECU that can effectively cool an ECU and that also improves space efficiency in a vehicle.

A cooling structure for an in-vehicle ECU according to an aspect of the present disclosure includes:
a body component that is part of a vehicle body; and
an ECU attached to the body component.

The body component includes a heatsink on the back side of a portion of the body component to which the ECU is attached.

The body component is a single-piece aluminum diecast component including the heatsink.

Integrally casting the body component and the heatsink allows effective cooling of the ECU without significantly increasing the size of the heatsink. As a result, the ECU can be effectively cooled, and the space efficiency in the vehicle is also improved.

In this case, the heatsink may include a plurality of heat dissipation fins arranged parallel to each other or a plurality of heat dissipation pins arranged in a two-dimensional array.

This configuration increases the surface area of the heatsink and thus improves the heat dissipation effect of the heatsink.

In the above cooling structure, the body component may be a single-piece aluminum diecast component including a pair of side panels, a wheel arch, and a connecting panel.

The side panels are located spaced apart from each other in a vehicle width direction.

The wheel arch protrudes inward in the vehicle width direction from each of the side panels.

The connecting panel connects the side panels.

Each of the side panels may include a vehicle cabin side portion functioning as a side wall of a vehicle cabin.

The ECU may be attached to an inner surface of the vehicle cabin side portion in the vehicle width direction.

The heatsink may protrude from the opposite side of the side panel from the ECU toward the outside of a vehicle.

Attaching the ECU to the vehicle cabin side portion allows effective use of an unused space. Moreover, causing the heatsink to protrude toward the outside of the vehicle allows efficient heat dissipation from the ECU. Heat from the ECU is therefore less likely to reach an occupant in a front seat. Therefore, comfort of the occupant is maintained.

The cooling structure may further include
a resin cover that covers the ECU from the vehicle cabin side.

The ECU may include an aluminum case, and may be screwed to the body component with the aluminum case in contact with the body component.

Providing the resin cover improves design quality and reduces heat transfer from the ECU to the occupant. Moreover, providing the case of the ECU that is made of aluminum with high thermal conductivity or a material mainly containing aluminum allows more efficient cooling of the ECU.

The technique disclosed in the present specification allows efficient cooling of an ECU and also improves space efficiency in a vehicle.

### BRIEF DESCRIPTION OF THE DRAWINGS

Features, advantages, and technical and industrial significance of exemplary embodiments of the disclosure will be described below with reference to the accompanying drawings, in which like signs denote like elements, and wherein:

FIG. 1 is a perspective view illustrating a vehicle body and a frame in a front part of a vehicle;

FIG. 2 is a perspective view of the vehicle cabin side portion viewed from the outside in the vehicle width direction;

FIG. 3 is a cross-sectional view of a region around a portion to which an ECU is attached; and

FIG. 4 is a perspective view illustrating another example of the heatsink.

### DETAILED DESCRIPTION OF EMBODIMENTS

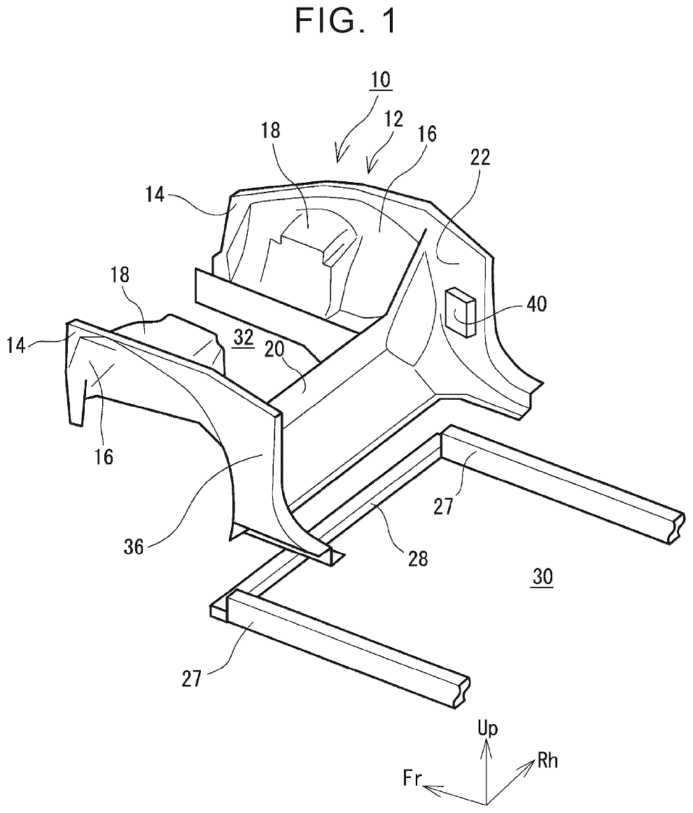

Hereinafter, a cooling structure for an ECU 40 will be described with reference to the drawings. FIG. 1 is a perspective view illustrating a vehicle body and a frame in a front part of a vehicle. In the drawings, Fr, Up, and Rh indicate the front, upper, and right sides of the vehicles, respectively.

The vehicle shown in FIG. 1 is a four-wheeled vehicle mainly used for transportation of people. A body component 10 is disposed in the front part of the vehicle. The body component 10 is a component that is part of the vehicle body. In this example, the body component 10 is a single-piece aluminum diecast component 12 including a pair of side panels 14, a pair of wheel arches 16, and a connecting panel 20. The aluminum diecast component 12 is of course mainly composed of aluminum or an aluminum alloy, and has high thermal conductivity. As is apparent from FIG. 1, the aluminum diecast component 12 is a large component having the pair of wheel arches 16. Such a large aluminum diecast component 12 is manufactured by a large diecasting technique called gigacasting or megacasting.

The side panel 14 of the body component 10 (aluminum diecast component 12) is a panel material that functions as a side wall of the vehicle. As shown in FIG. 1, part of each side panel 14 protrudes inward in the vehicle width direction. This protruding portion serves as the wheel arch 16. A suspension tower 18 is connected to the wheel arch 16. The suspension tower 18 is also formed integrally with the wheel arch 16 etc. by aluminum diecasting.

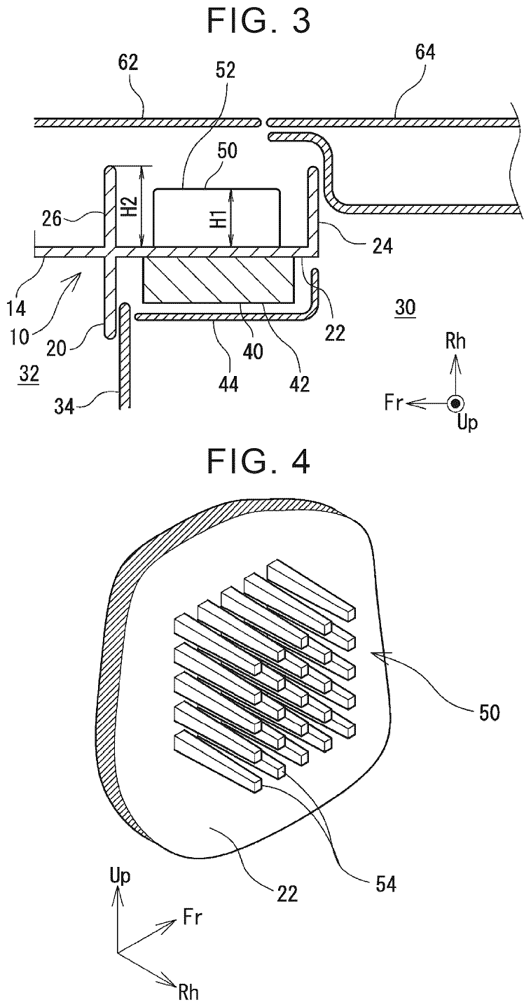

The pair of right and left side panels 14 is connected by a connecting panel 20. The connecting panel 20 is a panel member extending in the vehicle width direction, and its both ends in the vehicle width direction are connected to the side panels 14. A dash panel 34 (not shown in FIG. 1, see FIG. 3) is attached to the connecting panel 20. The dash panel 34 is a partition wall that separates the vehicle cabin 30 and the power unit compartment 32. Therefore, the space forward of the connecting panel 20 is the power unit compartment 32, and the space rearward of the dash panel 34 is the vehicle cabin 30. A portion of the side panel 14 that is located forward of the connecting panel 20 functions as a side wall of the power unit compartment 32. A portion of the side panel 14 that is located rearward of the connecting panel 20 functions as a side wall of the vehicle cabin 30. Hereinafter, the portion functioning as the side wall of the vehicle cabin 30 is referred to as a “vehicle cabin side portion 22”.

The body component 10 is fixed to a frame member of the vehicle. In the example of FIG. 1, the vehicle includes, as a frame member, a pair of rockers 27 extending in the vehicle front-rear direction and a cross member 28 connecting the pair of rockers 27. The body component 10 is fixed to the rockers 27 and the cross member 28.

Here, as described above, the vehicle cabin side portion 22 is a front side wall of the vehicle cabin 30, and is located in the vicinity of a lower limb of an occupant seated on the front seat. In the present embodiment, the ECU 40 is attached to the vehicle cabin side portion 22. The ECU 40 is a device that performs an arithmetic process on electric signals input from various sensors mounted on a vehicle by a microcomputer, and controls driving of various actuators mounted on the vehicle. The ECU 40 attached to the body component 10 may be an individual ECU that controls driving of a particular device (e.g., an engine ECU or a battery ECU), or may be an integrated ECU that integrates a plurality of ECUs mounted on a vehicle. In any case, the ECU 40 includes a signal circuit for calculating an electric signal, a power supply circuit for supplying power to the signal circuit, and an aluminum case 42 for accommodating the power supply circuit. As the ECU 40 is driven, a current flows through an electronic element (for example, a semiconductor element) incorporated in the signal circuit and the power supply circuit, and generates heat. If the ECU 40 becomes excessively high in temperature due to this heat generation, the ECU 40 may be damaged or malfunctioned. Further, since the ECU 40 is located in the vicinity of the lower limb of the occupant, there is a possibility that the comfort of the occupant may be impaired due to the high temperature of the ECU 40.

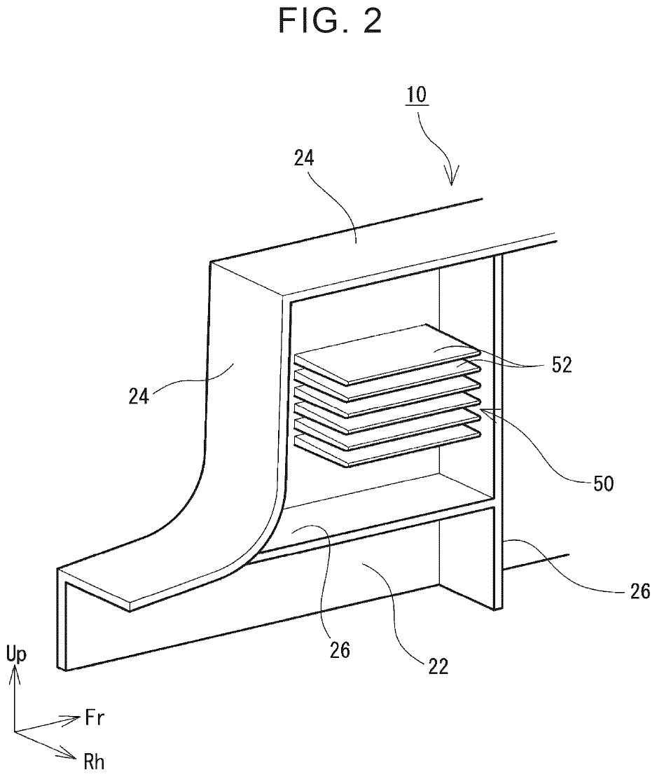

Therefore, in the present embodiment, in order to cool the ECU 40 more efficiently, the ECU 40 is attached to the body component 10 and a heatsink 50 is formed on the body component 10. Hereinafter, this will be described with reference to FIGS. 2 and 3.

FIG. 2 is a perspective view of the vehicle cabin side portion 22 to which the ECU 40 is attached as viewed from outside in the vehicle width direction. FIG. 3 is a cross-sectional view of a region around a portion to which the ECU 40 is attached. As shown in FIGS. 1 and 2, the ECU 40 is screwed to a surface of the vehicle cabin side portion 22 on the vehicle cabin 30 side. At this time, part of the aluminum case 42 of the ECU 40 contacts the vehicle cabin side portion 22. Through this contacting portion, the heat generated in the ECU 40 is efficiently transferred to the body component 10. In the present embodiment, the ECU 40 is fastened using a screw. However, the ECU 40 may be attached to the vehicle cabin side portion 22 in other manners as long as it is secured against the body component 10. For example, the ECU 40 may be fastened with a clip, fitted, or attached with an adhesive tape. The aluminum case 42 may be in direct contact with the vehicle cabin side portion 22, but another highly thermally conductive member may be interposed between the aluminum case 42 and the vehicle cabin side portion 22. For example, a thermally conductive grease or a thermal pad may be disposed between the aluminum case 42 and the vehicle cabin side portion 22 to fill the gap therebetween. Further, in this embodiment, the aluminum case 42 containing aluminum as a main component is used, the housing of the ECU 40, as long as it is possible to transfer the heat generated in the ECU 40 to the outside, may be other configurations.

Further, a resin cover 44 is attached to the vehicle cabin side portion 22. The resin cover 44 is a box-shaped member made of resin that covers the ECU 40 from the vehicle cabin 30. By providing the resin cover 44, heat from the ECU 40 toward the periphery of the lower limb of the occupant is blocked. As a result, an increase in temperature around the lower extremities of the occupant can be suppressed, and the comfort of the occupant can be improved. Further, by providing the resin cover 44, since the ECU 40 is hidden, the design of the vehicle cabin is improved.

The heatsink 50 is formed on the other side of the ECU 40 with the vehicle cabin side portion 22 interposed therebetween. The heatsink 50 is cast integrally with the body component 10. With such a configuration, a dedicated process for separately forming and attaching the heatsink 50 becomes unnecessary, and the cost and labor required for installing the heatsink 50 can be reduced. Casting the heatsink 50 integrally with the body component 10 eliminates a joint between the portion to which the ECU 40 is attached (that is, the vehicle cabin side portion 22) and the heatsink 50. This eliminates the thermal resistance caused by the joint, thereby improving the efficiency of heat transfer from the vehicle cabin side portion 22 to the heatsink 50.

As shown in FIGS. 2 and 3, the heatsink 50 includes a plurality of heat dissipation fins 52 arranged at intervals in an up-down direction. Each of the heat dissipation fins 52 is a member in the form of a substantially flat plate extending outward in the vehicle width direction from the vehicle cabin side portion 22. In this example, the thickness direction of the heat dissipation fin 52 is substantially parallel to the up-down direction. Providing the plurality of heat dissipation fins 52 increases the overall surface area of the heatsink 50 and improves the heat dissipation efficiency. This allows the ECU 40 located on the other side of the heatsink 50 to be cooled efficiently.

Here, as shown in FIGS. 2 and 3, the body component 10 has, at its upper and rear edges, folded portions 24 extending in the vehicle width direction. A plurality of ribs 26 is formed on the outer surface of the body component 10 in the vehicle width direction. Providing the folded portions 24 and the ribs 26 increases the section modulus of the body component 10 and improves the rigidity of the body component 10. The protruding dimension H1 of the heat dissipation fins 52 is smaller than the protruding dimension H2 of the folded portions 24 and part of the ribs 26. Therefore, even if the heat dissipation fins 52 are provided, the body size of the body component 10 does not increase. In other words, in this example, the heatsink 50 is formed in a dead space formed by the folded portions 24 and the ribs 26. Forming the heatsink 50 in such a dead space reduces a decrease in space efficiency due to mounting of the heatsink 50.

As is described repeatedly, the heatsink 50 is cast integrally with the body component 10. Therefore, the heat generated in the ECU 40 is transmitted not only to the heatsink 50 but also to the body component 10. The main component of the body component 10 is aluminum or an aluminum alloy having high thermal conductivity. The body component 10 is a very large component having a large surface area. By transferring heat to the body component 10, the heat dissipation efficiency of the ECU 40 is further improved.

As shown in FIG. 3, the front fender panel 62 is disposed on the vehicle width direction outer side from the vehicle cabin side portion 22. Further, a front side door 64 is disposed behind the front fender panel 62. Since the heatsink 50 is surrounded by the front fender panel 62 and the front side door 64, it cannot be visually recognized from the outside. As a result, even if the heatsink 50 is provided, the design of the vehicle can be maintained high. Providing the heatsink 50 increases the section modulus of the body component 10 and further improves the rigidity of the body component 10.

As is apparent from the above description, in the present embodiment, the ECU 40 is attached to the body component 10, and the heatsink 50 integral with the body component 10 is provided on the opposite side from the ECU 40. With this configuration, the ECU 40 can be cooled effectively while improving the space efficiency in the vehicle.

However, the configuration described so far is an example, and other configurations may be changed as long as the configuration described in claim 1 is provided. For example, in the above description, the heatsink 50 includes a plurality of heat dissipation fins 52 arranged in the up-down direction. However, the heatsink 50 may have other configurations as long as it is integral with the body component 10. For example, the heat dissipation fins 52 of the heatsink 50 may be arranged in a front-rear direction instead of in the up-down direction. In this case, each heat dissipation fin 52 is disposed in such an attitude that the thickness direction thereof is parallel to the front-rear direction. The heat dissipation fins 52 may be arranged side by side in a direction inclined in the front-rear direction and the up-down direction. For example, in a case where traveling wind flows around the heatsink 50, the plurality of heat dissipation fins 52 may be arranged side by side in an inclined direction so that the heat dissipation fins 52 are parallel to the flow of the traveling wind. As shown in FIG. 4, the heatsink 50 may include a plurality of heat dissipation pins 54 arranged in a two-dimensional array.

In the above description, the body component 10 is described as a large single-piece aluminum diecast component 12 including two wheel arches 16. However, the body component 10 to which the heatsink 50 is attached may have other configurations as long as it is part of the vehicle body. For example, the body component 10 may be provided on each of the right and left sides. That is, the body component 10 may have one of the right and left wheel arches 16, and may not have the other wheel arch 16.

In the above description, the body component 10 disposed in the front part of the vehicle is described as an example. However, the ECU 40 and the heatsink 50 may be attached to the body component 10 disposed in a different portion such as in the rear part of the vehicle rather than in the front part of the vehicle.

What is claimed is:

1. A cooling structure for an in-vehicle electronic control unit, the cooling structure comprising:
a body component that is part of a vehicle body; and
an electronic control unit attached to the body component, wherein:
the body component includes a heatsink on a back side of a portion of the body component to which the electronic control unit is attached; and
the body component is a single-piece aluminum diecast component including the heatsink.

2. The cooling structure according to claim 1, wherein the heatsink includes a plurality of heat dissipation fins arranged parallel to each other or a plurality of heat dissipation pins arranged in a two-dimensional array.

3. The cooling structure according to claim 1, wherein:
the body component is a single-piece aluminum diecast component including a pair of side panels, a wheel arch, and a connecting panel, the side panels being located spaced apart from each other in a vehicle width direction, the wheel arch protruding inward in the vehicle width direction from each of the side panels, and the connecting panel connecting the side panels;
each of the side panels includes a vehicle cabin side portion functioning as a side wall of a vehicle cabin;
the electronic control unit is attached to an inner surface of the vehicle cabin side portion in the vehicle width direction; and
the heatsink protrudes from an opposite side of the side panel from the electronic control unit toward outside of a vehicle.

4. The cooling structure according to claim 3, further comprising a resin cover that covers the electronic control unit from the vehicle cabin side,
wherein the electronic control unit includes an aluminum case, and is screwed to the body component with the aluminum case in contact with the body component.
